(19) United States
(12) Patent Application Publication
(10) Pub. No.: US 2025/0266659 A1
(43) Pub. Date: Aug. 21, 2025

(54) LASER PULSE GENERATOR AND METHOD FOR GENERATING A LASER PULSE

(71) Applicant: TRUMPF Laser GmbH, Schramberg (DE)

(72) Inventors: Michael HARTEKER, Rottweil (DE); Thomas HAAS, Hardt (DE); Joachim BONATH, Hausach (DE); Simon STRAUB, Schramberg (DE)

(21) Appl. No.: 19/200,700

(22) Filed: May 7, 2025

Related U.S. Application Data
(63) Continuation of application No. PCT/EP2023/080938, filed on Nov. 7, 2023.

(30) Foreign Application Priority Data
Nov. 11, 2022 (DE) 10 2022 129 873.6

(51) Int. Cl. H01S 5/042

(52) U.S. Cl. CPC H01S 5/0428

(57) ABSTRACT

A laser pulse generator includes a pulse shape generation device. The pulse shape generation device includes a pulse shape memory for storing data, a digital-to-analog converter connected to the pulse shape memory, a first connection for supplying a clock signal, and a second connection for outputting an output signal. The digital-to-analog converter is configured to generate the output signal in time with the clock signal arriving at the first connection. The laser pulse generator further includes a synchronization circuit. The synchronization circuit includes a third connection for connecting a trigger signal line transmitting a trigger signal. The synchronization circuit is connected to the second connection. The laser pulse generator further includes a clock stopping element connected to the first connection. The synchronization circuit is configured to control the clock stopping element according to the trigger signal and the output signal output at the second connection.

### CROSS REFERENCE TO RELATED APPLICATIONS

This application is a continuation of International Application No. PCT/EP2023/080938 (WO 2024/100013 A1), filed on Nov. 7, 2023, and claims benefit to German Patent Application No. DE 10 2022 129 873.6, filed on Nov. 11, 2022. The aforementioned applications are hereby incorporated by reference herein.

### FIELD

Embodiments of the present invention relate to a laser pulse generator and a method for generating a laser pulse.

### BACKGROUND

A laser signal generator is known, for example, from CN 213547471 U and DE 10 2016 212 929 A1.

Laser diodes generate a laser pulse by controlling a driver of the laser diode with a laser pulse shape. Laser pulse shapes may be output in a simple manner via a digital-to-analog converter. The memory contents of a pulse shape memory are output with an output clock via the digital-to-analog converter. In the case of so-called pulse-on-demand triggering, started by an operator, an output jitter may occur since the start event or trigger event does not necessarily correlate to the output clock of the memory or digital-to-analog converter.

Both DE 10 2016 212 929 A1 and CN 213547471 U use a logic module, in particular an FPGA, to generate a laser pulse shape. With such logic circuits, it is not possible to generate nanosecond laser pulses with a duration in the 25 nanosecond range without jitter.

### SUMMARY

Embodiments of the present invention provide a laser pulse generator. The laser pulse generator includes a pulse shape generation device. The pulse shape generation device includes a pulse shape memory for storing data, a digital-to-analog converter connected to the pulse shape memory, a first connection for supplying a clock signal, and a second connection for outputting an output signal. The digital-to-analog converter is configured to generate the output signal in time with the clock signal arriving at the first connection. The laser pulse generator further includes a synchronization circuit. The synchronization circuit includes a third connection for connecting a trigger signal line transmitting a trigger signal. The synchronization circuit is connected to the second connection. The laser pulse generator further includes a clock stopping element connected to the first connection. The synchronization circuit is configured to control the clock stopping element according to the trigger signal and the output signal output at the second connection.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic illustration of a laser pulse generator according to some embodiments; and

FIG. 2 shows graphs for explaining the functionality of the laser pulse generator according to some embodiments.

### DETAILED DESCRIPTION

Embodiments of the present invention provide a laser pulse generator and a method for generating a laser pulse with which a laser pulse may be generated with low output jitter, in particular a laser pulse which can be shaped in nanosecond steps. According to embodiments of the invention, a laser pulse generator having
a) a pulse shape generation device, comprising
   a pulse shape memory for storing data and a digital-to-analog converter connected thereto,
   a first connection for supplying a clock signal,
   a second connection for outputting an output signal, the digital-to-analog converter generating an output signal in time with a clock signal arriving at the first connection, which output signal is output at the second connection,
b) a synchronization circuit, which comprises a third connection for connection of a trigger signal line transmitting a trigger signal and is connected to the second connection,
c) a clock stopping element, which is connected to the first connection, the synchronization circuit being designed to control the clock stopping element according to the trigger signal and the output signal output at the second connection.

With the laser pulse generator according to embodiments of the invention, nanosecond laser pulses with an adjustable temporal shape may be generated. The temporal shape memory may be adjusted via the data stored in the pulse shape memory. The pulse shape memory may be filled via a micro-controller. The micro-controller may be connected to the pulse shape memory via a bus, in particular an SPI bus.

With the laser pulse generator according to embodiments of the invention, it is, in particular, possible to carry out the steps in which the laser pulse is to be shaped within a few nanoseconds or even within the sub-nanosecond range. The laser pulse may be requested arbitrarily, i.e. randomly. The request takes place via the trigger signal on the trigger signal line. With the laser pulse generator according to embodiments of the invention, the jitter of the laser pulse, which is generated in response to the output signal, is less than two nanoseconds. The laser pulse generator is preferably configured without an FPGA (field programmable gate array) or similar logic circuit.

The pulse shape memory may be integrated in the digital-to-analog converter. The contents of the pulse shape memory may be output cyclically in time with the clock signal, which may be in the range between 50 MHz-2.5 GHz. In response to a trigger signal and a specific state of the output signal, the clock signal may be stopped by accordingly controlling the clock stopping signal, which is preferably connected to a clock unit, in particular to a clock signal generator. Subsequently, in particular after a predetermined time, the clock signal may be reenabled and sent to the digital-to-analog converter in a defined manner so that an output signal which corresponds to a laser pulse shape is generated with minimal jitter, which output signal may be sent to an amplifier, connected upstream of a laser diode, to generate a laser pulse.

The synchronization circuit may comprise a monitoring element for monitoring the output signal. In particular, the monitoring element may be designed to monitor an edge of the signal or whether the output signal exceeds or falls short of a reference value. It may therefore be ensured that the clock signal is not stopped until the output signal of the digital-to-analog converter is at a specific location. It may therefore be ensured that, with each trigger event, the clock signal is not stopped until the pulse shape memory is at a precisely defined location.

The synchronization circuit may comprise a control element connected to the clock stopping element, which control element is connected to the third connection. It may thus be ensured that the clock stopping element is stopped only if a laser pulse is requested, i.e. a trigger signal is present.

The control element may be designed as a logic module.

The control element may be advantageously connected to the monitoring element. Therefore, both the trigger signal and the output signal of the monitoring element may be supplied to the control element. Only if a corresponding signal combination is present may the clock signal be stopped by controlling the clock stopping element accordingly.

The control element advantageously comprises a time element. The time element causes the clock signal to be reenabled after a predetermined time. The time element may be programmable, so that different predetermined times may be programmed.

A switching element may be connected to the second connection, which switching element is controlled by the synchronization circuit, in particular the control element. The switching element may be controlled such that the output signal is only relayed to an amplifier if synchronization has taken place.

Embodiments of the invention also provide a method for generating a laser pulse having the steps:
a) outputting data, in particular a digitally encoded pulse shape, from a pulse shape memory to a digital-to-analog converter (DAC);
b) generating an output signal in the DAC in time with a clock signal of a clock unit and outputting the output signal,
c) the clock signal being synchronized, taking into account the output signal.

In this way, an output signal from which a laser pulse is generated may be generated with low jitter.

The output signal may be monitored, in particular in terms of its value or its edges. In particular, the clock signal may be stopped if the output signal falls below a predetermined value.

In response to a trigger signal, the clock signal may be suspended for a predetermined time. It may be provided that the clock signal is suspended only if the trigger signal is applied on the one hand and the output signal satisfies a predetermined condition on the other.

In response to the trigger signal, the output signal may be relayed to an amplifier connected upstream of a laser diode. This may take place with a time delay, specifically if a predetermined time has elapsed once the trigger signal is applied and the output signal assumes a predetermined value.

Exemplary embodiments of the invention are described below with reference to the figures of the drawing. The features shown therein should not necessarily be seen as being drawn to scale and are illustrated in such a way that the characteristic features may be made clearly visible. The various features may each be realized individually or together in any desired combinations.

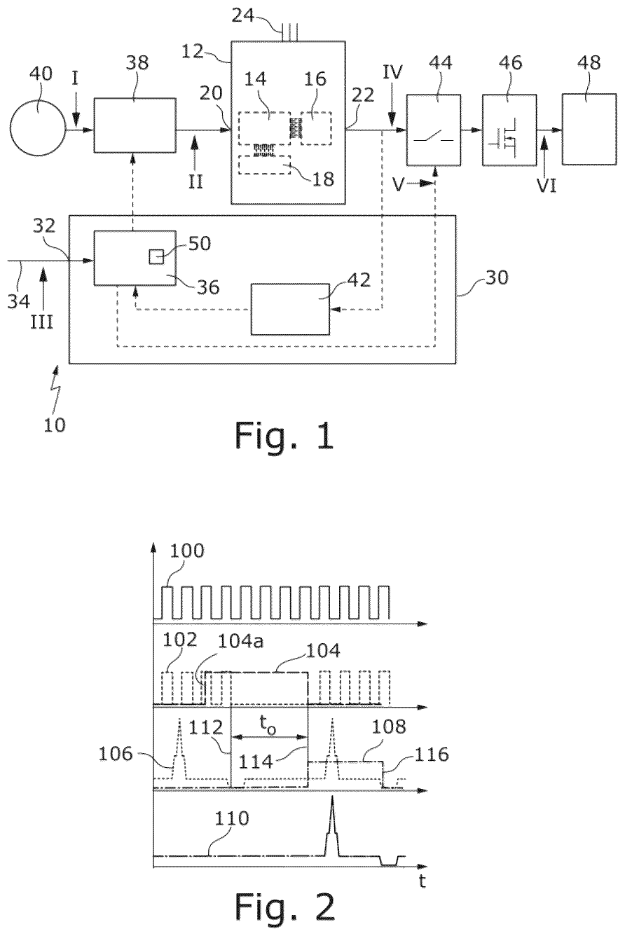

FIG. 1 shows a laser pulse generator 10. The laser pulse generator comprises a pulse shape generation device 12. This comprises a pulse shape memory 14 and a digital-to-analog converter 16. The pulse shape memory 14 in the exemplary embodiment shown is connected to a ring counter 18. The contents of the pulse shape memory 14 may be output cyclically with the aid of the ring counter 18 when a clock signal, in particular a clock signal >50 MHz, is applied at a first connection 20. The digital-to-analog converter 16 generates an analog output signal from the output data, which output signal is output at the second connection 22. The shape of the output signal is specified by the data stored in the pulse shape memory 14. The shape of the output signal may therefore correspond, in particular, to a laser pulse shape. The pulse shape generation device 12 comprises an interface 24 via which a micro-controller may be connected, by means of which micro-controller the pulse shape memory 14 may in turn be filled with data. The pulse shape memory 14 may comprise 64 memory locations.

Since the data memory contents are output cyclically with the aid of the ring counter 18, temporal synchronization with an external signal is not possible. The pulse pattern in the pulse shape memory is output continuously.

In order to still realize synchronization, a synchronization circuit 30 is provided. The synchronization circuit 30 comprises a third connection 32 for connection of a trigger signal line 34 transmitting a trigger signal. The synchronization circuit 30 comprises a control element 36, which is used to respond to the trigger signal transmitted on the signal line 34. The synchronization circuit 30, and, in particular, the control element 36 thereof, is connected to a clock stopping element 38. The clock stopping element 38 is connected to a clock signal generator 40 or can be connected to such a clock signal generator. In the exemplary embodiment shown, the clock signal generator 40 is connected to the first connection 20 via the clock stopping element 38. In response to the trigger signal transmitted on the trigger signal line 34, the control element 36 may control the clock stopping element 38 in order to prevent the clock signal of the clock signal generator 40 from being sent to the first connection 20. Therefore, the clock signal for the digital-to-analog converter 16 and the pulse shape memory 14 may be switched off by the clock stopping element 38. However, the clock signal should be stopped only if the output signal which is output at the connection 22 is at a specific location. This specific location may be identified by a monitoring element 42 of the synchronization circuit 30. The monitoring element 42 is connected to the connection 22 for this purpose.

If it is therefore identified by the monitoring element 42 that the output signal is at a specific location and a corresponding trigger signal is present, the clock stopping element 38 is controlled by the control element 36 in order to stop the clock. At the same time, the switching element 44 is controlled, in particular closed, by the control element 36 in order to output the next pulse of the pulse shape generation device 12 to the amplifier 46 upon restarting the clock at connection 20.

After a predetermined time, for example 100 nanoseconds, the clock stopping element 38 is again controlled by the control element 36 in order to reenable the clock signal. The clock signal now controls the ring counter 18 and the digital-to-analog converter 16 again. The pulse shape stored in the pulse shape memory 14 is output again until a certain location in the pulse pattern is reached and the monitoring element 42 responds again. As a result, the control element 36 receives a reset command and again controls the switching element 44 in order to prevent the output signal from being transmitted to the amplifier 46. The switching element 44 here is controlled, in particular opened, by the control element 36 in such a way that the output signal of the pulse shape generation device 12 is prevented from being relayed to the amplifier 46 and, via this, to the laser diode 48.

A laser diode 48 is driven by the amplifier 46.

The functionality is outlined with reference to the graphs in FIG. 2. The signal 100 corresponds to the signal output by the clock signal generator 40 at the location I in FIG. 1. The signal 102 corresponds to the signal at the location II at the first connection 20. The signal 104 corresponds to a trigger signal at the location III in FIG. 1.

The signal 106 corresponds to the output signal at the location IV in FIG. 1 at the second connection 22. The signal 108 corresponds to the signal at the location V in FIG. 1. The signal 110 corresponds to the signal at the location VI at the input of the laser diode 48.

If the control element 36 therefore identifies a rising edge 104a of the trigger signal 104 and it is furthermore signaled by the monitoring element 42 that the signal 106 at the second connection 22 is below a predetermined reference value, the clock stopping element 38 is controlled by the control element 36 in order to prevent the clock signal 100 from being output to the pulse shape generation device 12. This point in time is denoted by the line 112. After a predetermined time t0, which may be stored in the time element 50, has elapsed, the control element 36 controls the clock stopping element 38 again so that the clock signal is again output to the pulse generation device 12. At the same time, the control element 36 controls the switching element 44 so that the output signal 106 may be output to the amplifier 46. The output signal 106 is generated again from the location 114 due to the clock signal again being applied. The amplifier 46 amplifies the output signal 106 and delivers the signal 110 to the laser diode 48. If the monitoring device 42 again identifies that the output signal 106 is at a specific position, in particular falls below a specific value, the control element 36 is reset and the switching element 44 is opened, which takes place at the location 116.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A laser pulse generator, comprising:
a pulse shape generation device, comprising
a pulse shape memory for storing data,
a digital-to-analog converter connected to the pulse shape memory,
a first connection for supplying a clock signal, and
a second connection for outputting an output signal,
wherein the digital-to-analog converter is configured to generate the output signal in time with the clock signal arriving at the first connection,
a synchronization circuit comprising a third connection for connecting a trigger signal line transmitting a trigger signal, the synchronization circuit being connected to the second connection, and
a clock stopping element connected to the first connection, the synchronization circuit being configured to control the clock stopping element according to the trigger signal and the output signal output at the second connection.

2. The laser pulse generator as claimed in claim 1, wherein the synchronization circuit comprises a monitoring element for monitoring the output signal.

3. The laser pulse generator as claimed in claim 2, wherein the synchronization circuit comprises a control element connected to the clock stopping element, the control element being connected to the third connection.

4. The laser pulse generator as claimed in claim 3, wherein the control element is connected to the monitoring element.

5. The laser pulse generator as claimed in claim 3, wherein the control element comprises a time element.

6. The laser pulse generator as claimed in claim 1, further comprising a switching element connected to the second connection, the switching element being controlled by the synchronization circuit.

7. A method for generating a laser pulse, the method comprising:
outputting a digitally encoded pulse shape from a pulse shape memory to a digital-to-analog converter;
generating an output signal in the digital-to-analog converter in time with a clock signal of a clock unit, and outputting the output signal, and
synchronizing the clock signal, taking into account the output signal.

8. The method as claimed in claim 7, further comprising monitoring the output signal.

9. The method as claimed in claim 7, further comprising, in response to a trigger signal, suspending the clock signal for a predetermined time.

10. The method as claimed in claim 9, further comprising, in response to the trigger signal, relaying the output signal to an amplifier connected upstream of a laser diode.
